(19) United States
(12) Patent Application Publication
(10) Pub. No.: US 2008/0017963 A1
(43) Pub. Date: Jan. 24, 2008

(54) SI-SUBSTRATE AND STRUCTURE OF OPTO-ELECTRONIC PACKAGE HAVING THE SAME

(76) Inventor: Hung-Yi Lin, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/612,491

(22) Filed: Dec. 19, 2006

(30) Foreign Application Priority Data
Jul. 24, 2006 (TW) 095126950

(51) Int. Cl. H01L 23/02

(52) U.S. Cl. 257/678

(57) ABSTRACT

Disclosed herein is a structure of opto-electronic package having Si-substrate. The Si-substrates are manufactured in batch utilizing the micro-electromechanical processes or the semiconductor processes, so that these Si-substrates are made with great precision and full of varieties. Base on the material characteristic of the Si-substrate, and the configuration of the components, such as the connecters, opto-electronic devices, depressions, solder bumps, etc., the present invention can improve the optical effect, the heat dissipating effect, and the reliability of the opto-electronic package structure, and simplifies the complexity of the opto-electronic package structure.

### BACKGROUND OF THE INVENTION

1. Field of the Invention

The present invention generally relates to the field of opto-electronic package structures, and more particularly, to an opto-electronic package structure formed by the micro-electromechanical processes or the semiconductor processes.

2. Description of the Prior Art

In recent years, a new application field of high illumination light emitting diodes (LEDs) has been developed. Different from a common incandescent light, a cold illumination LED has the advantages of low power consumption, long device lifetime, no idling time, and quick response speed. In addition, since the LED also has the advantages of small size, vibration resistance, suitability for mass production, and ease of fabrication as a tiny device or an array device, it has been widely applied in display apparatuses and indicating lamps used in information, communication, and consumer electronic products. The LEDs are not only utilized in outdoor traffic signal lamps or various outdoor displays, but are also very important components in the automotive industry. Furthermore, the LEDs work well in portable products, such as cellular phones and as backlights of personal data assistants. These LEDs have become necessary key components in the highly popular liquid crystal displays because they are the best choice when selecting the light source of the backlight module.

Please refer to FIG. 1 and FIG. 2. FIG. 1 is a schematic top view diagram showing a prior art surface mount device (SMD) LED package structure 10, and FIG. 2 is a cross section diagram illustrating the prior art SMD LED package structure 10 along 1-1′ line shown in FIG. 1. As shown in FIG. 1 and FIG. 2, an SMD LED package structure 10 comprises a cup-structure substrate 12, a lead frame 14, an opto-electronic device 16, conducting wires 18 and 20, and a sealant 22. As a semiconductor device comprising a positive electrode and a negative electrode (not shown), the opto-electronic device 16 is illuminated by receiving power from an external voltage source and connected to the lead frame 14 by the conducting wires 18 and 20. Situated in the cup-structure substrate 12, the lead frame 14 is extended to the outer surface of the cup-structure substrate 12, which will be electrically connected to a printed circuit board (PCB) 24.

In order to construct the prior art LED package 10, the cup-structure substrate 12 should be completed first, and then the sealant 22 covers the opto-electronic device 16 by means of molding or sealant injection. After the construction of the prior art LED package 10 is completed, at least a surface mounting process is performed to mount the LED packages 10 on the PCB 24 individually. As a result, it is almost impossible to produce the LED packages 10 in batch, and the manufacturing process of the electronic products is too complicated and tedious. As applied in a LED package 10 with high power, the cup-structure substrate 12 of the opto-electronic device 16 is unavoidably overheated, which may eventually result in a reduction of light intensity or failure of the entire device. Due to the significantly large volume of the single LED package 10 and the heat radiating demand required by a LED package 10 with high power, the designed size and the heat dissipating efficiency of the whole LED package 10 are greatly limited.

### SUMMARY OF THE INVENTION

It is the primary object of the present invention to provide an opto-electronic package structure having a Si-substrate. Accordingly, the present invention can improve the optical effect, the heat dissipating effect, and the reliability of the opto-electronic package structure, the opto-electronic package structure can be manufactured in batch, and the complexity of the opto-electronic package structure can be simplified.

According to the claimed invention, a Si-substrate having flip-chip bumps is disclosed. The Si-substrate has a top surface and a bottom surface. In addition, the Si-substrate includes a plurality of electric-conducting holes, a plurality of connecters, and a plurality of flip-chip bumps positioned on the top surface of the Si-substrate. Each of the electric-conducting holes penetrates through the Si-substrate from the top surface to the bottom surface. The connecters include a plurality of substrate-penetrating electric-conducting wires and at least a heat-conducting wire. Each of the substrate-penetrating electric-conducting wires extends from the top surface of the Si-substrate to the bottom surface of the Si-substrate through the electric-conducting holes, and the heat-conducting wire covers portions of the bottom surface of the Si-substrate. The flip-chip bumps are electrically connected to the substrate-penetrating electric-conducting wires.

Since the Si-substrates can be produced in a batch system utilizing micro-electromechanical processes or semiconductor processes, these Si-substrates are made with great precision and full of varieties. According to the characteristics of Si-substrate and the arrangement of the components, such as the connecters, the opto-electronic device, the cup-structure and the flip-chip bump on Si-substrate, the present invention can simplify the complexity of the components in the opto-electronic package structure, and increase the optical effect, the heat-dissipating effect and the packaging reliability of the opto-electronic package structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view diagram showing a prior art surface mount device (SMD) LED package structure.

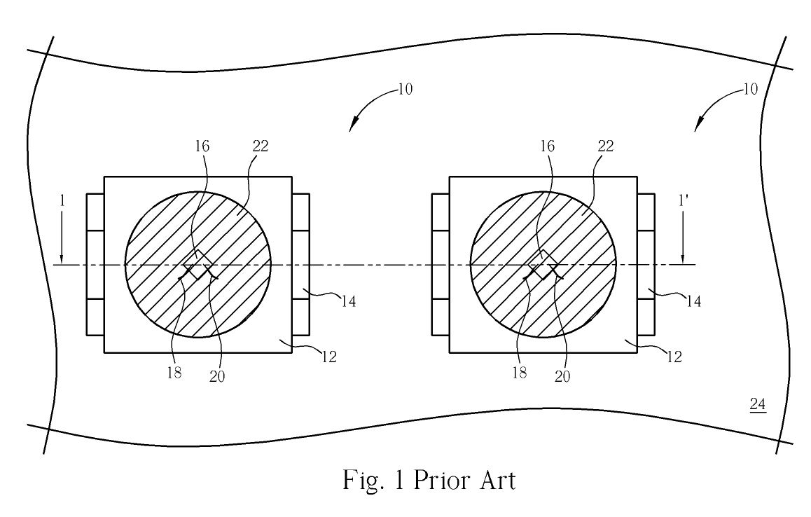

FIG. 2 is a cross section diagram illustrating the prior art SMD LED package structure along 1-1′ line shown in FIG. 1.

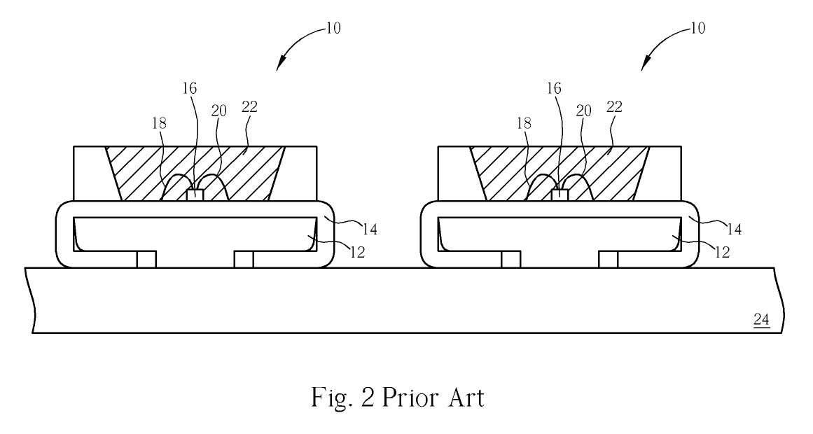

FIG. 3 is a cross-sectional schematic diagram illustrating a Si-substrate having flip-chip bumps according to a first preferred embodiment of the present invention.

FIG. 4 is a schematic diagram illustrating an opto-electronic package structure having a Si-substrate according to a second preferred embodiment of the present invention.

FIG. 5 is a cross-sectional schematic diagram illustrating the opto-electronic package structure along line 5-5′ shown in FIG. 4.

FIG. 6 is a cross-sectional schematic diagram illustrating opto-electronic package structures having Si-substrates according to a third preferred embodiment of the present invention.

### DETAILED DESCRIPTION

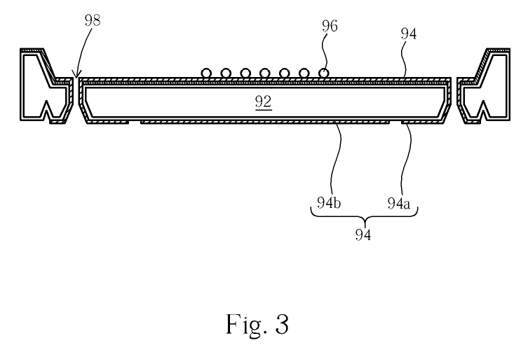

Please refer to FIG. 3. FIG. 3 is a cross-sectional schematic diagram illustrating a Si-substrate having flip-chip bumps according to a first preferred embodiment of the present invention. It is to be understood that the drawings are not drawn to scale and are served only for illustration purposes. As shown in FIG. 3, a Si-substrate 92 includes a plurality of connecters 94 and a plurality of flip-chip bumps 96. The Si-substrate 92 itself has a plurality of electric-conducting holes 98, and each electric-conducting hole 98 penetrates the Si-substrate 92 from the top surface to the bottom surface. The connecters 94 include a plurality of substrate-penetrating electric-conducting wires 94a and at least a heat-conducting wire 94b, and each substrate-penetrating electric-conducting wire 94 extends from the top surface of the Si-substrate 92 to the bottom surface of the Si-substrate 92 through the electric-conducting holes 98. The heat-conducting wire 94b covers parts of the bottom surface of the Si-substrate 92, and is preferably formed on the position of the Si-substrate 92, where the heat should be transfer outward. It should be noticed that the flip-chip bumps 96 are formed directly on the top surface of the Si-substrate 92, and electrically connected to the substrate-penetrating electric-conducting wires 94a.

Because the present invention can produce the Si-substrate by means of the micro-electromechanical process or the semiconductor process, bumps can be directly formed on the surface of the Si-substrate, and thereafter connect to the follow-up opto-electronic device. In light of this structure, a plurality of the Si-substrates 92 having flip-chip bumps 96 in this embodiment can be produced in one wafer simultaneously. After all components of the above-mentioned Si-substrates 92 are completed, the Si-substrates 92 can be separated from each other by means of a wafer sawing process, and each Si-substrates 92 can be electrically connected to a corresponding opto-electronic device directly through the flip-chip bumps 96 of each Si-substrate 92. Therefore, the present invention benefits from low cost and consistency with standard micro-electromechanical processes and semiconductor processes. Furthermore, the present invention has no need to form the flip-chip bumps 96 on the Si-substrates 92 one by one during the packaging processes, so it significantly increases the production of packaging.

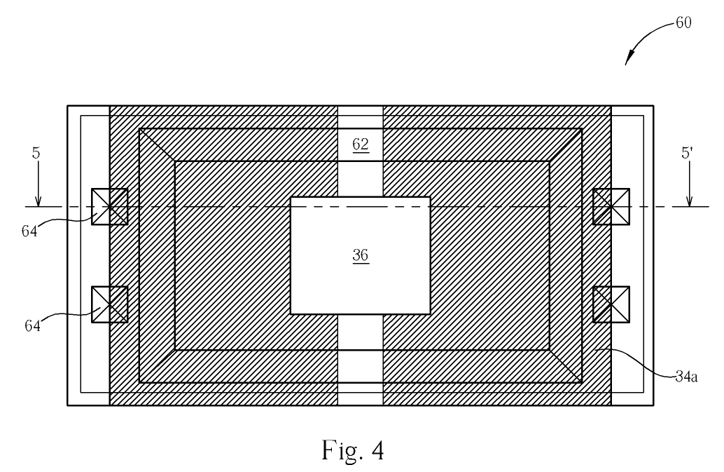

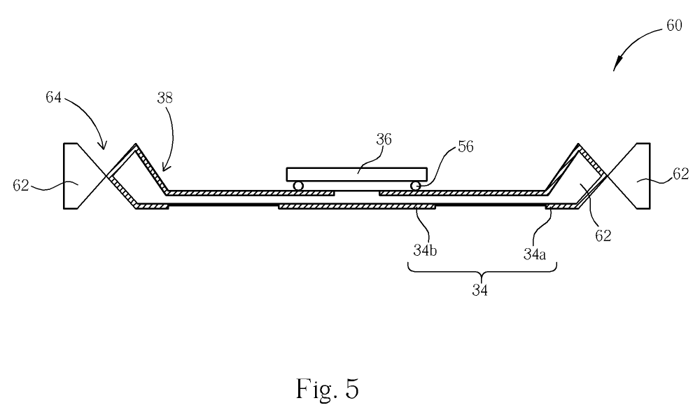

Please refer to FIG. 4 and FIG. 5. FIG. 4 is a schematic diagram illustrating an opto-electronic package structure 60 having a Si-substrate 62 according to a second preferred embodiment of the present invention, and FIG. 5 is a cross-sectional schematic diagram illustrating the opto-electronic package structure 60 along line 5-5′ shown in FIG. 4, wherein like number numerals designate similar or the same parts, regions or elements. As shown in FIG. 3 and FIG. 4, an opto-electronic package structure 60 includes a Si-substrate 62, a plurality of connecters 34 and a plurality of solder bumps 56. The material of the Si-substrate 62 includes polysilicon, amorphous silicon or single-crystal silicon. In addition, the Si-substrate 62 can be a rectangle silicon chip or a circular silicon chip, and can include integrated circuits or passive components therein. The Si-substrate 62 has a top surface and a bottom surface. A cup-structure 38 is included in the top surface of the Si-substrate 62 so as to contain an opto-electronic device 36 therein. A plurality of electric-conducting holes 64 can be included in the Si-substrate 62, and each electric-conducting hole 64 penetrates through the Si-substrate 62 from the top surface to the bottom surface.

The connecters 34 include a plurality of substrate-penetrating electric-conducting wires 34a and can further include at least a heat-conducting wire 34b. In order to form the substrate-penetrating electric-conducting wires 34a and the heat-conducting wire 34b simultaneously, a metal layer is first formed on the top surface of the Si-substrate 62, the bottom surface of the Si-substrate 62 and sidewalls of the electric-conducting holes 64 utilizing a plating process or a deposition process. Next, the substrate-penetrating electric-conducting wires 34a and the heat-conducting wire 34b are separated by means of an etching process so that the substrate-penetrating electric-conducting wires 34a and the heat-conducting wire 34b do not electrically connect to each other. Each substrate-penetrating electric-conducting wire 34a extends from the top surface of the Si-substrate 62 to the bottom surface of the Si-substrate 62 through at least one of the electric-conducting holes 64. The heat-conducting wire 34b covers portions of the bottom surface of the Si-substrate 62. In application, the heat-conducting wire 34b can be a flat metal layer having large area, and each substrate-penetrating electric-conducting wires 34a can be a flat metal layer having large area or a metal circuit layer having circuit therein.

After all components of the Si-substrate 62 are completed, the Si-substrate 62 can be diced from a wafer, and each Si-substrate 62 can be electrically connected to the corresponding opto-electronic device 36 directly through the flip-chip bumps 56 of the Si-substrate 62. The opto-electronic device 36 can be a light-emitting component or a photo sensor, such as a light emitting diode (LED), a photo diode, a digital micromirror device (DMD), or a liquid crystal on silicon (LCOS), but is not limited to those devices. The opto-electronic device 36 can be fixed onto the top surface of the Si-substrate 62 by a fixing gel. Furthermore, the positive electrode and negative electrode of the opto-electronic device 36 are then connected individually to the positive electrode terminal and the negative electrode terminal defined on the substrate-penetrating electric-conducting wires 34a, using a flip-chip technique. Subsequently, the positive electrode and negative electrode of the opto-electronic device 36 are connected to a printed circuit board (not shown in the figure) through the substrate-penetrating electric-conducting wires 34a positioned on the bottom surface of the Si-substrate 62.

In addition to above-mentioned components, the opto-electronic package structure 60 of the present invention can further include a packaging material layer (not shown in the figure), an insulation layer (not shown in the figure) and an optical film (not shown in the figure). The packaging material layer is composed of mixtures containing resin, wavelength converting materials, fluorescent powder, and/or light-diffusing materials. The packaging material layer is packaged onto the Si-substrate 62 by a molding or sealant injection method so as to increase the product reliability of the opto-electronic package structure 60, and to control the optical effect of the opto-electronic device 36. The optical film can be a coat having a high refractive index located on the bottom and the sidewall of the cup-structure 38, and it can further increase the light quantity propagating from the opto-electronic package structure 60 in combination with the cup-structure 38.

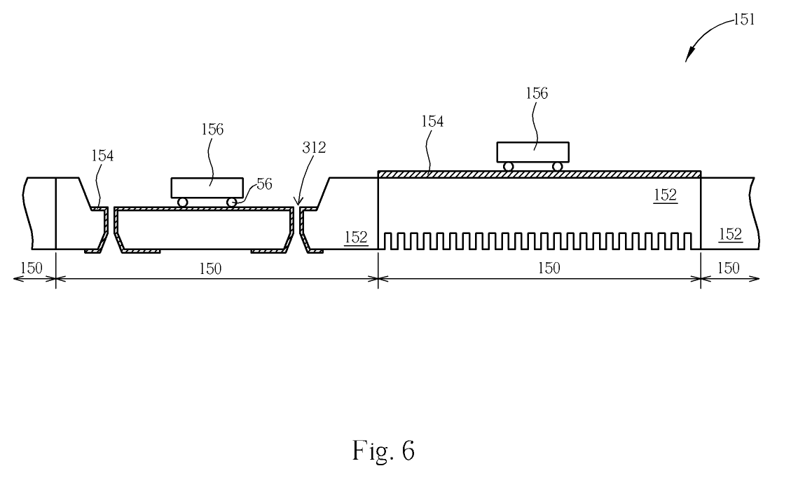

In other preferred embodiments of the present invention, the Si-substrates can be diced from a wafer after the packaging material layer is packaged onto the Si-substrate by a molding or sealant injection method to package the opto-electronic package structure. Please refer to FIG. 6. FIG. 6 is a cross-sectional schematic diagram illustrating opto-electronic package structures 150 having Si-substrates 152 according to a third preferred embodiment of the present invention. As shown in FIG. 6, a plurality of opto-electronic package structures 150 are defined in a silicon wafer 151, and each opto-electronic package structure 150 includes a Si-substrate 152. Each of the Si-substrates 152 includes a plurality of connecters 154, a plurality of solder bumps 56 electrically connected to the connecters 154, and at least an opto-electronic device 156 electrically connected to the corresponding solder bumps 56. Accordingly, at least one of the Si-substrates 152 includes electric-conducting holes 312, and each connector 154 on this Si-substrates 152 extends from the top surface of the Si-substrate 152 to the bottom surface of the Si-substrate 152 through at least one of the electric-conducting holes 312. On other hand, at least one of the opto-electronic devices 156 is located on the top surface of an un-hollow Si-substrates 152. The bottom surface of the un-hollow Si-substrate 152 can be a fin structure so as to increase the heat-dissipating efficiency.

After all components of the opto-electronic package structures 150 are completed, the Si-substrates 152 can be separated from each other by means of a wafer sawing process, and each opto-electronic package structure 150 is electrically connected to the corresponding printed circuit board through the connecters of each Si-substrate 152.

Because the present invention chooses the Si-substrate to form the opto-electronic package structure, and the heat transfer coefficient of silicon material is quite large, the heat-dissipating effect of the opto-electronic package structure can be increased. In addition, since silicon and an LED are both made from semiconductor materials, the coefficient of thermal expansion (CTE) of silicon is approximately equal to the CTE of the LED. Therefore, using silicon to form the packaging substrate can increase the reliability of the produced opto-electronic package structure.

Furthermore, the opto-electronic package structure having the Si-substrate can be made in a batch system utilizing micro-electromechanical processes or semiconductor processes. According to the characteristics of the Si-substrate and the arrangement of the components, such as the connecters, the opto-electronic device, the cup-structure and the flip-chip bump on Si-substrate, the present invention can simplify the complexity of the components in the opto-electronic package structure, and increase the optical effect, the heat-dissipating effect and the packaging reliability of the opto-electronic package structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A silicon-substrate (Si-substrate) having flip-chip bumps, the Si-substrate having a top surface and a bottom surface, and the Si-substrate comprising:
a plurality of electric-conducting holes, each of the electric-conducting holes penetrating through the Si-substrate from the top surface to the bottom surface;
a plurality of connecters, comprising a plurality of substrate-penetrating electric-conducting wires and at least a heat-conducting wire, each of the substrate-penetrating electric-conducting wires extending from the top surface of the Si-substrate to the bottom surface of the Si-substrate through the electric-conducting holes, the heat-conducting wire covering portions of the bottom surface of the Si-substrate; and
a plurality of flip-chip bumps positioned on the top surface of the Si-substrate, and electrically connected to the substrate-penetrating electric-conducting wires.

2. The Si-substrate of claim 1, wherein the top surface of the Si-substrate comprises a cup-structure, and the flip-chip bumps are positioned in the cup-structure.

3. The Si-substrate of claim 2, wherein the electric-conducting holes penetrate portions of the Si-substrate positioned under the cup-structure.

4. The Si-substrate of claim 2, wherein the electric-conducting holes penetrate portions of the Si-substrate positioned around the cup-structures.

5. The Si-substrate of claim 1, wherein the substrate-penetrating electric-conducting wires positioned on the bottom surface of the Si-substrate contact a metal connecting layer, and are electrically connected to a printed circuit board through the metal connecting layer.

6. The Si-substrate of claim 1, wherein the flip-chip bumps are electrically connected to at least an opto-electronic device.

7. The Si-substrate of claim 1, wherein the heat-conducting wire is a flat metal layer having large area.
